(19) United States
(12) Patent Application Publication
(10) Pub. No.: US 2005/0087223 A1
(43) Pub. Date: Apr. 28, 2005

(54) Solar cell array

(75) Inventor: Mitsuhiro Yuasa, Minato-ku (JP)

Correspondence Address: CROWELL & MORING LLP;INTELLECTUAL PROPERTY GROUP, P.O. BOX 14300, WASHINGTON, DC, 20044-4300, US

(73) Assignee: Tokyo Electron Limited, Minato-ku (JP)

(21) Appl. No.: 10/937,507

(22) Filed: Sep. 10, 2004

(30) Foreign Application Priority Data
Sep. 10, 2003 (JP) 2003-318653

(51) Int. Cl. H01L 25/00

(52) U.S. Cl. 136/251

(57) ABSTRACT

On a semiconductor substrate having a control circuit layered thereon, an actuator and a solar cell are formed in a block. Thereafter, the actuator and solar cell are each divided into segments in order to form a solar cell array having a number of solar cells supported by respective actuators.

### BACKGROUND OF THE INVENTION

1. Field of the Invention

The present invention relates to a solar cell array, or more particularly, to a solar cell array comprising a plurality of solar cells each being supported by an actuator.

2. Description of the Related Art

In the past, a solar cell has been adopted as a power supply for equipment to be used without maintenance. In order to efficiently use sunlight, the solar cell must be placed with the cell surface oriented towards the sun. However, if the cell surface is oriented in a certain direction on a fixed basis, as an angle at which sunlight meets the earth varies depending on a time in a day or a season, photovoltaic efficiency is degraded. Consequently, an attempt has been made to design a movable solar cell and control the solar cell so that it will always face the sun. However, as the movable portion of the solar cell must be movable in a wide range, the movable portion is large in size. This makes it hard to design the whole system compactly. Moreover, if the movable portion breaks down, a serious drop in generated photovoltaic power takes place.

For example, even if a sensor or information processing equipment manufactured by applying micro-electromechanical system (MEMS) technology is left outdoors for use and the movable solar cell is adopted as a power supply, the large movable portion reduces the merit of a compact design realized by the MEMS technology. In the past, a technology having both the merit of equipment manufactured by applying the MEMS technology and the merit of the solar cell mixed therein has not been devised.

### SUMMARY OF THE INVENTION

The present invention addresses the foregoing problems. An object of the present invention is to provide a solar cell array manufacturing method making it possible to design a solar cell compactly, though the solar cell is movable, a solar cell array unit to be manufactured according to the manufacturing method, electronic equipment including a solar cell array, and a network accommodating pieces of electronic equipment.

According to the first aspect of the present invention, there is provided a manufacturing method for producing a solar cell array composed of a plurality of solar cells. Herein, an actuator and a solar cell are formed on a substrate on which a control circuit is layered, and the actuator and solar cell are each divided into segments in order to form a solar cell array having a plurality of solar cells supported by respective actuators. According to the method, a movable solar cell array composed of a number of solar cells can be manufactured readily. In this case, part of the actuator is supported by a sacrifical layer, and the sacrifical layer is removed at a solar cell array forming step. Moreover, the top of the actuator or the first layer of the solar cell is etched in order to form irregularities so that solar radiation can be utilized effectively.

According to the second aspect of the present invention, there are a solar cell array apparatus that has a plurality of solar cells supported by respective actuators and a solar cell array apparatus that is manufactured according to the aforesaid manufacturing method. A breakdown of an actuator can hardly lower the photovoltaic efficiency of the solar cell array. The actuator can be driven in order to maximize an amount of photovoltaic power generated by a solar cell. Moreover, a secondary cell or a capacitor may be included for storing photovoltaic power.

According to the third aspect of the present invention, there is provided electronic equipment including the solar cell array unit. The electronic equipment may include two spherical covers and make an inner spherical cover, which supports a solar cell array, movable in any desired direction. In this case, the cost and time required for installation of the electronic equipment including solar cells can be drastically reduced. Moreover, an antenna and a transmitting/receiving circuit may be included for the transmission or the reception of signals.

According to the fourth aspect of the present invention, there is provided an electronic equipment system that includes a plurality of pieces of electronic equipment each comprising an antenna, a transmitting/receiving circuit, and a solar cell array, and that autonomously serves as a network. In this case, a radiocommunication network can be constructed readily.

Other objects and aspects of the present invention will be apparent from the descriptions, of embodiments, that will be given below in conjunction with the appended drawings.

### BRIEF DESCRIPTION OF THE DRAWINGS

FIG. 1 schematically shows a solar cell array in accordance with a first embodiment of the present invention;

FIG. 2 is a sectional view showing an intermediate step of a solar cell array manufacturing method in accordance with a second embodiment of the present invention;

FIG. 3 is a sectional view showing the last step of the solar cell array manufacturing method in accordance with the second embodiment of the present invention; and

FIG. 4 schematically shows electronic equipment in accordance with a third embodiment of the present invention which includes a solar cell array.

### DESCRIPTION OF THE PREFERRED EMBODIMENTS

Referring to the drawings, embodiments of the present invention will be described below. To begin with, a method of manufacturing a solar cell array in accordance with an embodiment of the present invention will be described below. One of the features of the manufacturing method is that a solar cell array having a plurality of solar cells set in array is manufactured as a micro-electromechanical system (MEMS).

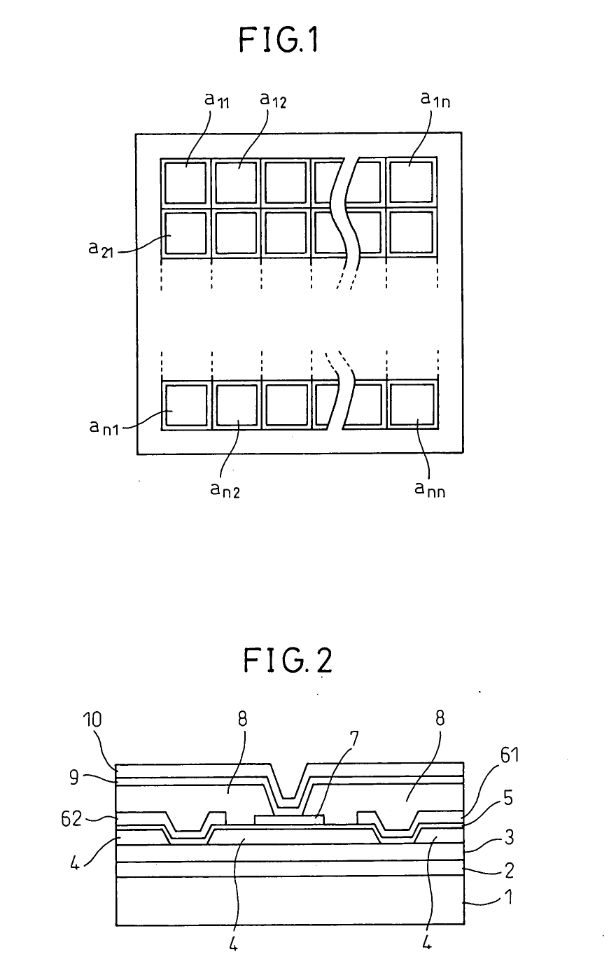

FIG. 1 is a schematic plan view showing a solar cell array in accordance with an embodiment of the present invention. The solar cell array includes solar cells aⱼₖ (where 1≦j, k≦n). Herein, the number of solar cells arranged horizontally is equal to the number of solar cells arranged vertically. Alternatively, the number of solar cells may be different between horizontal and vertical directions. Herein, for example, n is set to 32. Therefore, the solar cell array comprises 1024 (=32×32) cells aⱼₖ. As described later, each solar cell aⱼₖ has a mechanical drive, that is, an actuator, and can move or turn towards the sun so as to receive sunlight most efficiently. Thus, the solar cell array comprises a number of cells each having the drive. Therefore, even if ten of 1024 actuators break down, a decrease in a power output is 1% or less. Photovoltaic power can be stably supplied over a prolonged period of time. In contrast, if a photo voltaic device has a movable cell plate supported by only one actuator, the cell plate angle cannot be controlled after a breakdown of the actuator. This leads to a large decrease in a power output.

FIG. 2 is a sectional view showing a step in an intermediate stage of a solar cell array manufacturing process in accordance with the present embodiment. An oxide 2 is coated on a semiconductor substrate 1, on which an integrated circuit is formed, and is planarized through chemo-mechanical polishing (CMP). A metallic layer 3 is formed on the resultant oxide 2. A hinge 5 is formed via a first sacrifice layer 4. Hinge supporting posts 61 and 62 for supporting the hinge 5 and a yoke 7 are formed on the hinge 5. An actuator 9 is formed via a second sacrifice layer 8. At a subsequent step, the actuator 9 is divided into segments in association with cells, and the first and second sacrifice layers 4 and 8 are removed. Consequently, the actuator 9 becomes movable. This actuator forming process is known as a MEMS technology. (refer to, for example, Japanese Unexamined Patent Application Publication No. 5-333279).

According to the present embodiment, a solar cell 10 is layered or formed as one member on the actuator 9 formed as one member. FIG. 2 shows a cross-section of one cell included in a solar cell array. The actuator 9 and solar cell 10 are formed successively.

In order to increase the superficial area of a solar cell, the top of an actuator is etched to form irregularities. Otherwise, the top of an actuator may be planarized, and the first layer of a solar cell formed on the top of the actuator may be etched in order to form irregularities. Etching to be performed in order to provide microscopic irregularities may be wet etching. Alternatively, dry etching may be preceded by patterning in order to provide cyclic irregularities. For dry etching, an XeF2 gas may be adopted. Otherwise, plasma dry etching using a process gas that contains a halogen element, SF6, or NF3 may be adopted.

The solar cell 10 is of a layered type, made of, for example, a PIN amorphous silicon, and formed through plasma chemical vapor deposition (CVD) for fear the actuator 9 and semiconductor circuit may be adversely affected. The solar cell 10 is formed as one member on the actuator 9. The layers constituting the layered solar cell may be formed successively within a chamber included in a manufacturing system having a clustering tool or may be formed by sequentially changing gases within the same chamber.

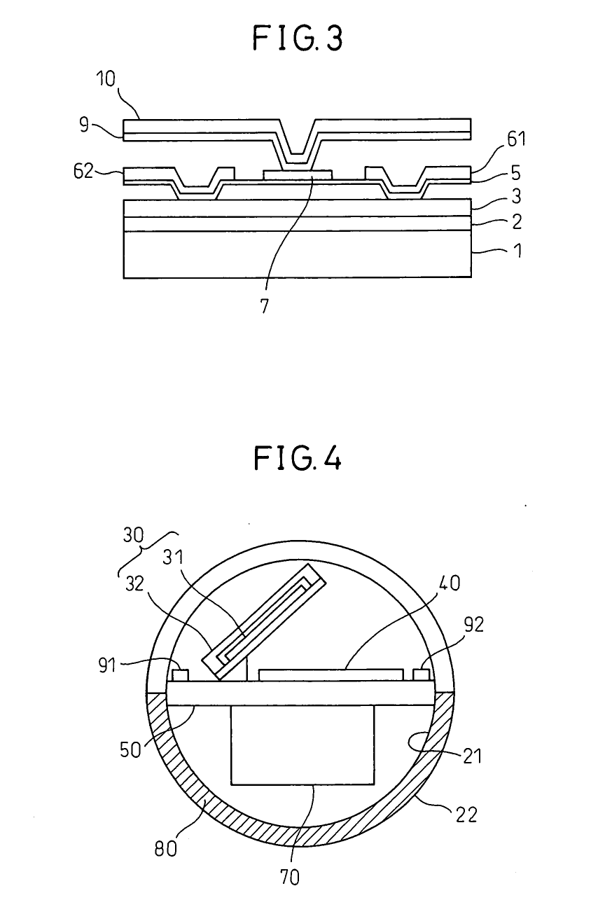

Thereafter, the actuator 9 and solar cell 10 are each divided into segments through plasma etching, and the first and second sacrifice layers 4 and 9 are removed so that a gap will be formed below the actuator 9. FIG. 3 shows the gap. The actuator 9 is driven with static electricity produced by a driving electrode opposed to the actuator 9.

Consequently, an array of, for example, 32 solar cells in rows and 32 solar cells in columns is constructed. According to the present invention, a solar cell array composed of a number of solar cells is formed as one member on an actuator. Thereafter, the solar cells are separated from one another. Thus, a solar cell array can be manufactured readily.

FIG. 4 shows an example of electronic equipment employing a solar cell array manufactured as mentioned above. The electronic equipment shown in FIG. 4 is adopted as a relay mainly for communications, and includes a transparent spherical inner cover 21 and a transparent spherical outer cover 22. The inner cover 21 and outer cover 22 can rotate relative to each other with a lubricant 80 between them. A substrate 50 formed with a flat member passing through the center of the cover is fixed to the inner cover 22. A solar cell array unit 30 having at least the face of a solar cell array 31 covered with a transparent package 32, and an electronic circuit unit 40 including an antenna and a transmitting/receiving circuit are mounted on one side of the substrate 50. The solar cell array unit 30 is supported at an appropriate angle with respect to the substrate. The angle is adjustable depending on a place of use. Moreover, a large-capacitance capacitor 70 is mounted on the other side of the substrate 50. The large-capacitance capacitor 70 is used to store generated photovoltaic power, and fills the role of a weight. Furthermore, permanent magnets 91 and 92 are disposed at positions, which are symmetrical to each other with respect to the center of the substrate, near the inner cover so that the directions of the magnetic lines of force around the magnets will be consistent with each other.

The present embodiment has the foregoing components and includes a dual-structure spherical body having the covers 21 and 22 with a lubricant between them. The large-capacitance capacitor 70 supported by the inner cover 21 fills the role of a weight. In whatever manner the electronic equipment is disposed, the solar cell array unit 30 is automatically located upwards. Moreover, the weights of components are balanced for fear the substrate 50 may tilt with respect to a horizontal line. The lubricant 80 is sealed in the gap between the covers 71 and 72. As long as the dual-structure spherical body can be freely rotated, the lubricant 80 need not be employed. Otherwise, any other supporting member may be adopted. A secondary cell that is a chargeable cell may be substituted for the large-capacitance capacitor 70 filling the role of a weight.

The permanent magnets 91 and 92 are used as magnetic needles for fixing a direction. Since the inner cover 21 supporting the substrate 50 is freely movable relative to the outer cover 22, the direction of the substrate 50 is automatically adjusted by the permanent magnets. Consequently, the direction of the solar cell array unit 30 can be adjusted, and photovoltaic power can be generated more efficiently. The solar cell array 31 is placed on the substrate 50 so that it will be oriented to the south in the Northern Hemisphere. Moreover, the angle of the array 31 is adjusted according to the latitude at which the electronic equipment is disposed. Specifically, the angle of the array 31 is consistent with a mean altitude of the sun measured at the installation site. In the present embodiment, the solar cells constituting the solar cell array can change their angles. Therefore, while an amount of generated photovoltaic power is monitored, each solar cell surface of the solar cell array unit is controlled to lie at an angle permitting a maximum amount of photovoltaic power. Consequently, the maximum amount of photovoltaic power can be obtained irrespective of the time of day or the season.

As far as the electronic equipment with solar cells having the foregoing components is concerned, once it is installed in a place where the electronic equipment can receive sunlight, the ability to generate a maximum amount of photovoltaic power is automatic. The time or cost required for installation can be reduced greatly. Moreover, in some places, the electronic equipment may be dispersed in the air from, for example, an aircraft or a helicopter. Nevertheless, the ability to generate a maximum amount of photovoltaic power can be drawn out.

As the electronic equipment in accordance with the embodiment has the electronic circuit unit 40, which includes an antenna and a transmitting/receiving circuit, mounted on the substrate 50, a network can be automatically constructed using pieces of electronic equipment that is identical to the electronic equipment in accordance with the embodiment and that can communicate with one another. Namely, a communication network can be readily constructed for a short period of time in, for example, a wide disaster-stricken area. Moreover, even in a desert, a jungle, or a mountainous district, as a cable need not be laid down, a communication network can be constructed without an adverse effect on a natural environment.

Furthermore, any appropriate sensor or electronic circuit can be mounted on the substrate. A signal acquired via a sensor can be transmitted to an information processing center or the like over a constructed network. Moreover, not only information or a signal but also photovoltaic power may be transmitted or received over the network. In this case, a required photovoltaic power can be transmitted to any place where the photovoltaic power is needed. Needless to say, the solar cell array in accordance with the present invention is usable under interior lighting.

1. A solar cell array manufacturing method comprising the steps of:
forming as layer a control circuit on a semiconductor substrate;
forming as layer an actuator on the control circuit;
forming a solar cell on the actuator; and
forming a solar cell array by dividing each of the actuator and solar cell into segments so as to form a solar cell array having a plurality of solar cells supported by respective actuators.

2. The solar cell array manufacturing method according to claim 1, wherein part of said actuator is supported by a sacrifice layer, and the sacrifice layer is removed at the solar cell array forming step.

3. The solar cell array manufacturing method according to claim 1, wherein at said actuator forming step, the top of said actuator is etched in order to form irregularities.

4. The solar cell array manufacturing method according to claim 3, wherein said etching is wet etching.

5. The solar cell array manufacturing method according to claim 3, wherein said etching is dry etching preceded by patterning.

6. The solar cell array manufacturing method according to claim 5, wherein said dry etching is dry etching employing an XeF2 gas.

7. The solar cell array manufacturing method according to claim 5, wherein said dry etching is plasma dry etching.

8. The solar cell array manufacturing method according to claim 6, wherein said plasma dry etching employs a process gas containing a halogen element.

9. The solar cell array manufacturing method according to claim 8, wherein said plasma dry etching employs a process gas containing SF6 or NF3.

10. The solar cell array manufacturing method according to claim 1, wherein at said solar cell forming step, the first layer of said solar cell is etched in order to form irregularities.

11. The solar cell array manufacturing method according to claim 10, wherein said etching is wet etching.

12. The solar cell array manufacturing method according to claim 10, wherein said etching is dry etching preceded by patterning.

13. The solar cell array manufacturing method according to claim 12, wherein said dry etching is dry etching employing an XeF2 gas.

14. The solar cell array manufacturing method according to claim 14, wherein said dry etching is plasma dry etching.

15. The solar cell array manufacturing method according to claim 14, wherein said plasma dry etching employs a process gas containing a halogen element.

16. The solar cell array manufacturing method according to claim 15, wherein said plasma dry etching employs a process gas containing SF6 or NF3.

17. The solar cell array manufacturing method according to claim 1, wherein at least part of said solar cell forming step is achieved through plasma CVD.

18. The solar cell array manufacturing method according to claim 1, wherein at said solar cell forming step, a solar cell having a layered structure is formed.

19. The solar cell array manufacturing method according to claim 18, wherein said layered structure is formed within a single apparatus.

20. The solar cell array manufacturing method according to claim 18, wherein said layered structure is formed by sequentially changing gases within a chamber.

21. A solar cell array apparatus comprising:
a semiconductor substrate having a control circuit layered thereon;
a plurality of actuators formed on the control circuit; and
solar cells layered on the plurality of actuators.

22. A solar cell array apparatus including a solar cell array that is manufactured according to the manufacturing method set forth in claim 1 and that has a plurality of solar cells supported by respective actuators.

23. The solar cell array apparatus according to claim 21, further comprising a control mechanism that drives the actuators so as to maximize an amount of photovoltaic power generated by said solar cells.

24. The solar cell array apparatus according to claim 21, further comprising a secondary cell or a capacitor in which photovoltaic power is stored.

25. The solar cell array apparatus according to claim 21, wherein said solar cells are packaged for purposes of protection, and a surface of a package facing a solar cell array is transparent.

26. Electronic equipment including said solar cell array device set forth in claim 21.

27. The electronic equipment according to claim 26, wherein said electronic equipment is enclosed with a transparent cover.

28. The electronic equipment according to claim 27, wherein said cover is spherical.

29. The electronic equipment according to claim 26, wherein the balance of weights of components is adjusted so that said solar cell array device will be automatically located upwards.

30. The electronic equipment according to claim 29, wherein a secondary cell or a capacitor is used as part of a weight in order to adjust said balance of weights.

31. The electronic equipment according to claim 28, wherein an outer cover having at least a spherical internal side is disposed outside said spherical cover.

32. The electronic equipment according to claim 26, wherein a permanent magnet is disposed so that said solar cell array will be automatically oriented in a desired direction.

33. The electronic equipment according to claim 31, wherein a lubricant is sealed in a gap between the spherical cover and the outer cover.

34. The electronic equipment according to claim 26, wherein an antenna and a transmitting/receiving circuit are included for transmission or reception of signals.

35. An electronic equipment system including a plurality of pieces of electronic equipment identical to the one set forth in claim 34, wherein the pieces of electronic equipment autonomously transmit or receive signals so as to construct a network.
